(19) United States
(12) Patent Application Publication
(10) Pub. No.: US 2025/0140558 A1
(43) Pub. Date: May 1, 2025

(54) METHOD OF FORMING PATTERNS, SEMICONDUCTOR MEMORY DEVICE, AND METHOD OF MANUFACTURING SEMICONDUCTOR MEMORY DEVICE

(71) Applicant: Samsung Electronics Co., Ltd., Suwon-si (KR)

(72) Inventors: Yeongsup SOHN, Suwon-si (KR); Seongbo SHIM, Suwon-si (KR); Moosong LEE, Suwon-si (KR); Jiyeon YI, Suwon-si (KR)

(73) Assignee: Samsung Electronics Co., Ltd., Suwon-si (KR)

(21) Appl. No.: 18/761,797

(22) Filed: Jul. 2, 2024

(30) Foreign Application Priority Data
Oct. 31, 2023 (KR) 10-2023-0148433

(51) Int. Cl. H01L 21/033; G03F 7/00; G03F 7/004; G03F 7/16; H01L 21/308; H01L 21/311; H01L 21/3213

(52) U.S. Cl. CPC H01L 21/0337; G03F 7/0035; G03F 7/162; G03F 7/167; G03F 7/70025; G03F 7/70033; G03F 7/7045; G03F 7/0042; H01L 21/3086; H01L 21/31144; H01L 21/32139

(57) ABSTRACT

A method of forming patterns includes forming an etch target film on a substrate having a first region and a second region, forming a hardmask structure on the etch target film in the first region and the second region, the hardmask structure including a plurality of hardmask layers, forming a first photoresist film on the hardmask structure in at least one of the first region and the second region, forming a first photoresist pattern in the second region by exposing and developing the first photoresist film, and forming a pattern from the etch target film by etching the hardmask structure and the etch target film by using the first photoresist pattern, wherein a top surface of the hardmask structure in the first region is exposed to the outside after the first photoresist film is developed.

### CROSS-REFERENCE TO RELATED APPLICATION

This application is based on and claims priority under 35 U.S.C. § 119 to Korean Patent Application No. 10-2023-0148433, filed on Oct. 31, 2023, in the Korean Intellectual Property Office, the disclosure of which is incorporated by reference herein in its entirety.

### BACKGROUND

The inventive concepts relate to a method of forming patterns, a semiconductor memory device, and a method of manufacturing the semiconductor memory device, and more particularly, to a method of forming patterns in a plurality of regions with different pattern densities, a method of manufacturing a semiconductor memory device using the method, and a semiconductor memory device.

With the recent rapid development of down-scaling of integrated circuit devices, the feature size of semiconductor memory devices is decreasing and the critical dimensions of patterns of semiconductor memory devices are also decreasing. Accordingly, the difficulty in processes is increasing when patterns having various shapes, sizes, and densities required for semiconductor memory devices are simultaneously formed.

### SUMMARY

The inventive concepts provide a method of forming patterns, by which the increase in the difficulty in processes of simultaneously forming patterns having various shapes, sizes, and densities in a plurality of regions is suppressed and a process margin is increased, and a method of manufacturing a semiconductor memory device by using the method of forming patterns.

The inventive concepts also provide a semiconductor memory device manufactured by these methods.

According to an aspect of the inventive concepts, there is provided a method of forming patterns. The method includes forming an etch target film on a substrate having a first region and a second region, forming a hardmask structure on the etch target film in the first region and the second region, the hardmask structure including a plurality of hardmask layers, forming a first photoresist film on the hardmask structure in at least one of the first region and the second region, forming a first photoresist pattern in the second region by exposing and developing the first photoresist film, and forming a pattern from the etch target film by etching the hardmask structure and the etch target film by using the first photoresist pattern, wherein a top surface of the hardmask structure in the first region is exposed to the outside after the first photoresist film is developed.

According to another aspect of the inventive concepts, there is provided a method of forming patterns. The method includes forming an etch target film on a substrate having a first region and a second region, forming a hardmask structure including a lower hardmask layer, a main hardmask layer, and an upper hardmask layer sequentially stacked on the etch target film, forming a first photoresist pattern on the hardmask structure by exposing the second region to light having a first wavelength, forming a hardmask pattern by removing the upper hardmask layer in the first region and removing at least a portion of the upper hardmask layer in the second region by using the first photoresist pattern as an etch mask, forming a second photoresist pattern on the main hardmask layer by exposing the first region to light having a second wavelength, and forming a pattern from the etch target film by using the hardmask pattern, wherein the first photoresist pattern is arranged only in the second region and the second photoresist pattern is arranged only in the first region.

According to still another aspect of the inventive concepts, there is provided a method of manufacturing a semiconductor memory device. The method includes forming an etch target film on a substrate having a cell array region and a peripheral circuit region, forming a hardmask structure on the etch target film in the cell array region and the peripheral circuit region, the hardmask structure including a plurality of hardmask layers, forming a first photoresist film on the hardmask structure in the cell array region and the peripheral circuit region, forming a first photoresist pattern in the peripheral circuit region by exposing and developing the first photoresist film, forming a second photoresist film on the hardmask structure in at least one of the cell array region and the peripheral circuit region, forming a second photoresist pattern covering the cell array region by exposing and developing the second photoresist film, and forming a pattern from the etch target film by etching the hardmask structure and the etch target film by using the first and second photoresist patterns, wherein a top surface of the hardmask structure in the cell array region is exposed to the outside after the first photoresist film is developed, and the second photoresist film is formed after at least one of the plurality of hardmask layers is removed.

### BRIEF DESCRIPTION OF THE DRAWINGS

Example embodiments will be more clearly understood from the following detailed description taken in conjunction with the accompanying drawings in which:

FIG. 1 is a block diagram of an example configuration of a semiconductor memory device according to example embodiments;

FIG. 2 is a plan view illustrating an example arrangement of the semiconductor memory device of FIG. 1;

FIG. 3 is a plan view illustrating an example arrangement of the semiconductor memory device of FIG. 1;

FIGS. 4 to 13 are cross-sectional views illustrating a method forming a pattern, according to example embodiments;

FIG. 14 is a schematic plane layout illustrating main elements in a cell array region in FIG. 2;

FIG. 15 is a plan view illustrating an example arrangement of conductive patterns in a peripheral circuit region of a semiconductor memory device, according to example embodiments; and

FIGS. 16A to 20B are cross-sectional views illustrating a method of manufacturing a semiconductor memory device, according to example embodiments.

### DETAILED DESCRIPTION OF EXAMPLE EMBODIMENTS

Hereinafter, example embodiments are described in detail with reference to the accompanying drawings. In the drawings, like numerals denote like elements and redundant descriptions thereof will be omitted.

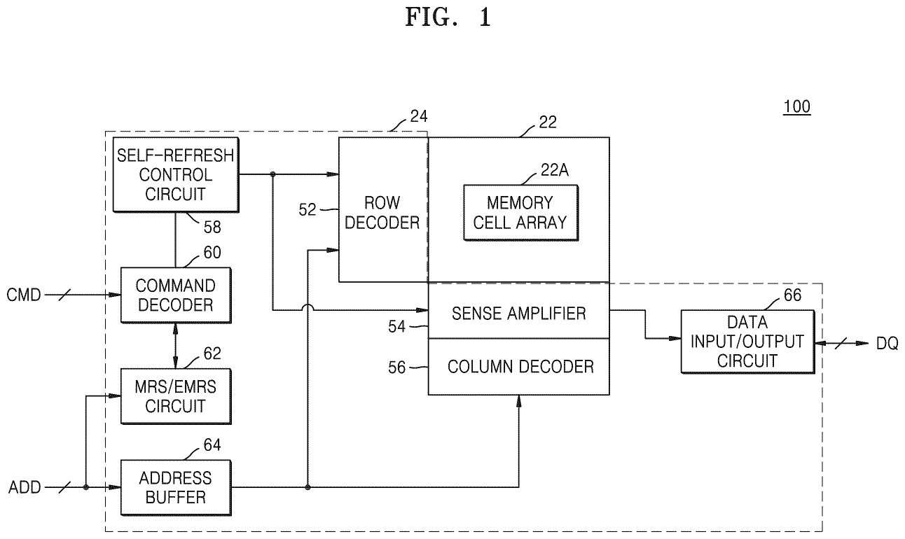

FIG. 1 is a block diagram of an example configuration of a semiconductor memory device according to example embodiments.

Referring to FIGS. 1, a semiconductor memory device 100 may include a first region 22 and a second region 24. The first region 22 may correspond to a memory cell region of a dynamic random access memory (DRAM) device and the second region 24 may correspond to a peripheral circuit region of the DRAM device. The first region 22 may include a memory cell array 22A. The second region 24 may include a row decoder 52, a sense amplifier 54, a column decoder 56, a self-refresh control circuit 58, a command decoder 60, a mode register set/extended mode register set (MRS/EMRS) circuit 62, an address buffer 64, and/or a data input/output circuit 66.

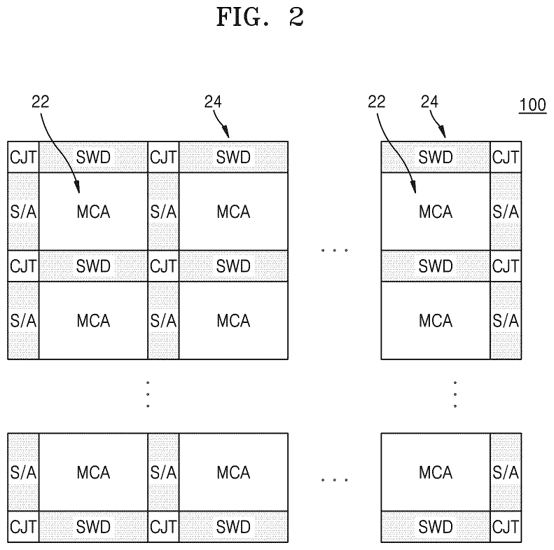

FIG. 2 is a plan view illustrating an example arrangement of the semiconductor memory device 100 of FIG. 1. FIG. 2 is described with reference to FIG. 1.

Referring to FIG. 2, the semiconductor memory device 100 may include a plurality of first regions 22. In a plan view, each of the first regions 22 may be surrounded by the second region 24.

Each of the first regions 22 may correspond to a cell array region MCA of a DRAM device and the second region 24 may correspond to a region, in which peripheral circuits of the DRAM device are formed, and a core region (hereinafter, referred to as a “peripheral circuit region”). In the first regions 22, the cell array region MCA may include the memory cell array 22A described above with reference to FIG. 1.

The second region 24 may include a sub-word line driver block SWD, a sense amplifier block S/A, and/or a conjunction block CJT. A plurality of bit line sense amplifiers may be arranged in the sense amplifier block S/A. The conjunction block CJT may be arranged at the intersection between the sub-word line driver block SWD and the sense amplifier block S/A. Power drivers and ground drivers, for driving the bit line sense amplifiers, may be alternately arranged in the conjunction block CJT. Peripheral circuits, such as an inverter chain and an input/output circuit, may be further arranged in the second region 24.

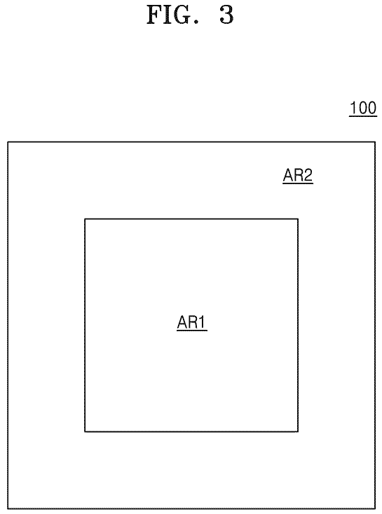

FIG. 3 is a plan view illustrating an example arrangement of the semiconductor memory device 100 of FIG. 1. FIG. 3 is described with reference to FIG. 1.

Referring to FIG. 3, the semiconductor memory device 100 may include a first region AR1 and a second region AR2, which have different pattern densities and shapes. For example, the first region AR1 may correspond to the cell array region MCA in FIG. 2 and the second region AR2 may correspond to the peripheral circuit region described with reference to FIG. 2. The first region AR1 may be a high-density region in which a pattern density is relatively high. The second region AR2 may be a low-density region in which a pattern density is relatively low.

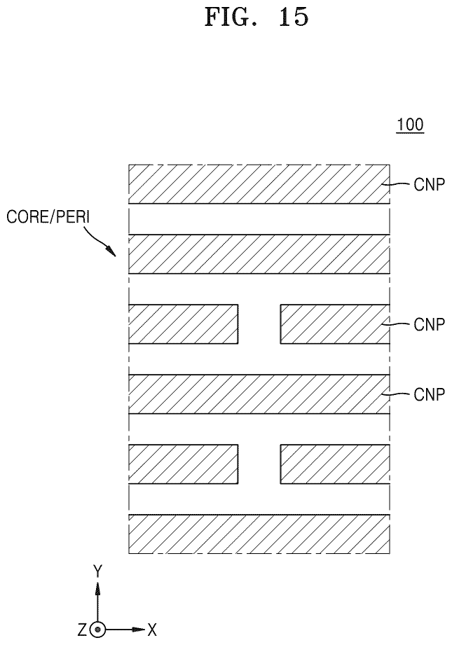

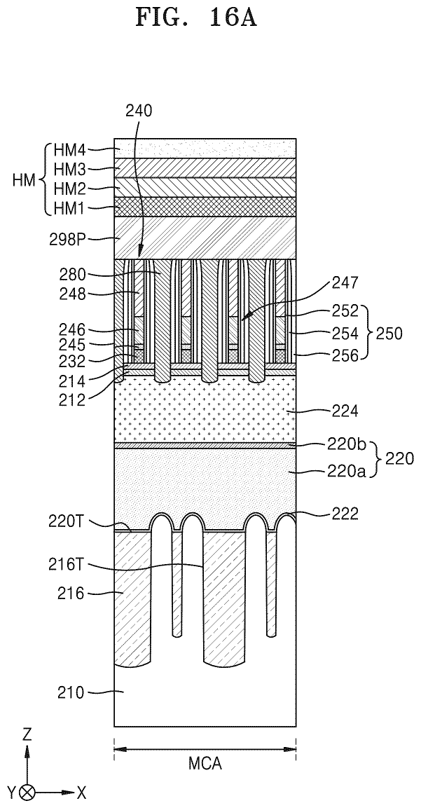

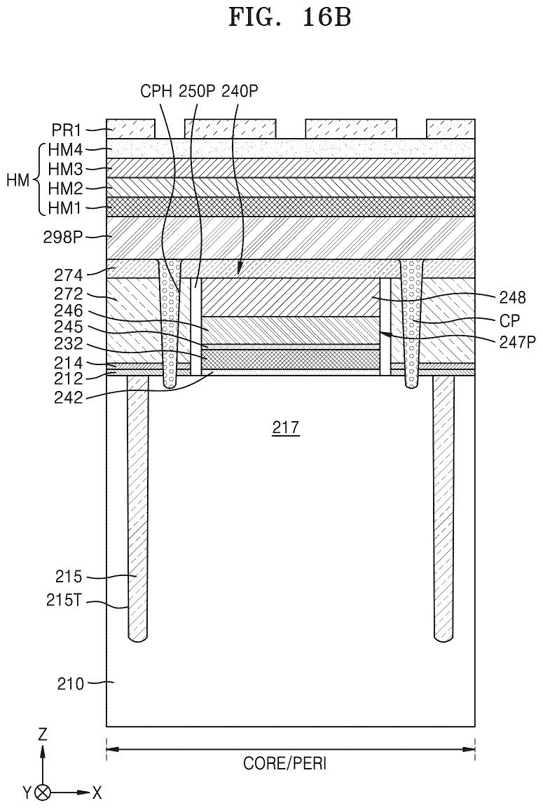

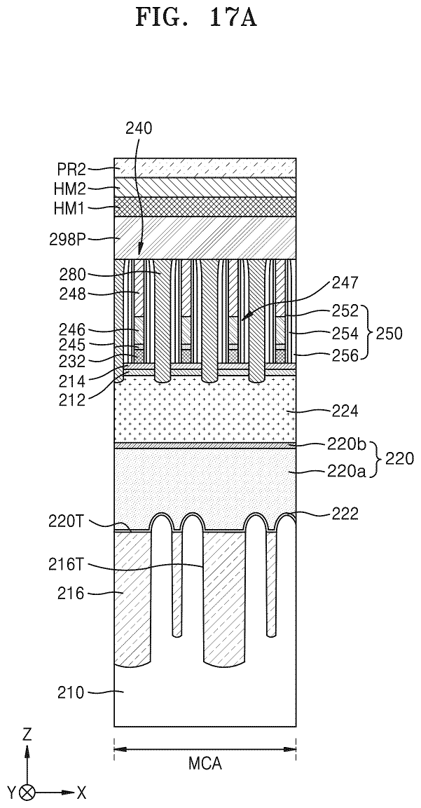

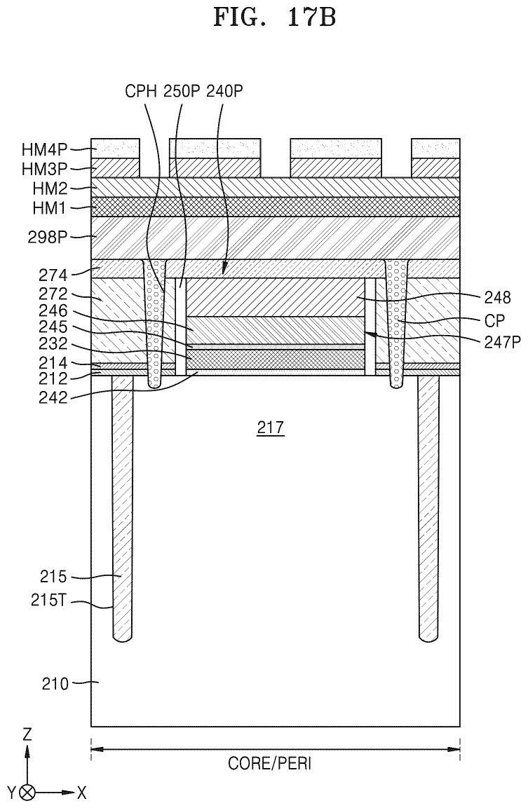

In the first region AR1, a plurality of patterns having a relatively small width may be apart from each other in a regular arrangement and repeatedly formed at a relatively small pitch. In the second region AR2, a plurality of patterns having irregular widths and lengths may be apart from one another by irregular distances and repeatedly formed at irregular pitches. Patterns respectively formed in the first region AR1 and the second region AR2 are described in detail with reference to FIGS. 14 and 15.

For example, the first region AR1 may correspond to the cell array region MCA of the semiconductor memory device 100. For example, a volatile memory cell array such as DRAM or a non-volatile memory cell array such as flash memory may be formed in the first region AR1. The second region AR2 may correspond to an edge region of the memory cell array or a peripheral circuit region, in which peripheral circuits electrically connected to cell arrays in the first region AR1 are formed.

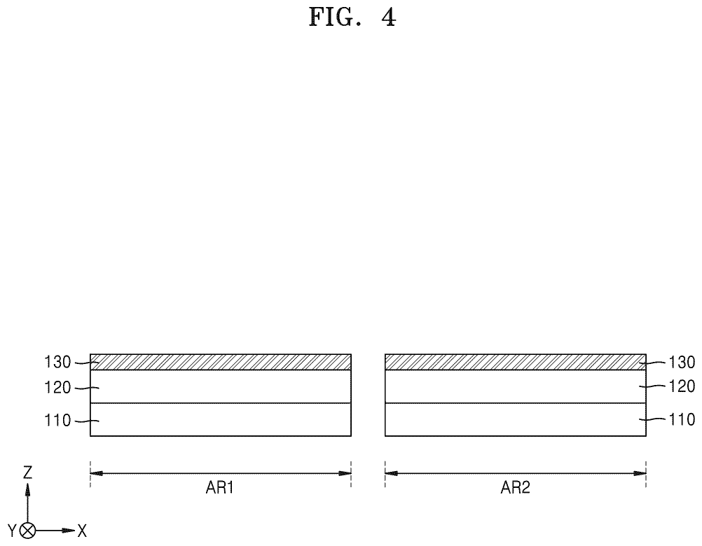

FIGS. 4 to 13 are cross-sectional views illustrating a method forming a pattern, according to example embodiments. FIGS. 4 to 13 illustrate a method of forming patterns only in the second region AR2 but not in the first region AR1.

Referring to FIG. 4, a lower structure 120 may be formed on a substrate 110. The level of the top surface of the lower structure 120 in the first region AR1 and the second region AR2 may be the same or substantially the same or similar. Herein, the term “level” refers to a height from the top surface of the substrate 110 in the vertical direction (the Z direction). An etch target film 130 may be formed on the lower structure 120.

The substrate 110 may include a semiconductor element, such as Si or Ge, or a compound semiconductor, such as SiC, GaAs, InAs, or InP. The lower structure 120 may include an insulating layer, a conductive layer, or a combination thereof. For example, the lower structure 120 may include structures including at least one conductive region. The conductive region may include a doped structure, a doped semiconductor layer, a metal layer, or a combination thereof. The lower structure 120 may include conductive regions, e.g., a wiring layer, a contact plug, and a transistor, and insulating films, which insulate the conductive regions from each other. The etch target film 130 may include an insulating pattern, a conductive pattern, or a combination thereof. In some example embodiments, the etch target film 130 may include a doped semiconductor, metal, conductive metal nitride, or a combination thereof.

Herein, a direction parallel with the main surface of the substrate 110 may be referred to as a horizontal direction (the X direction and/or the Y direction) and a direction perpendicular to the horizontal direction (the X direction and/or the Y direction) may be referred to as the vertical direction (the Z direction).

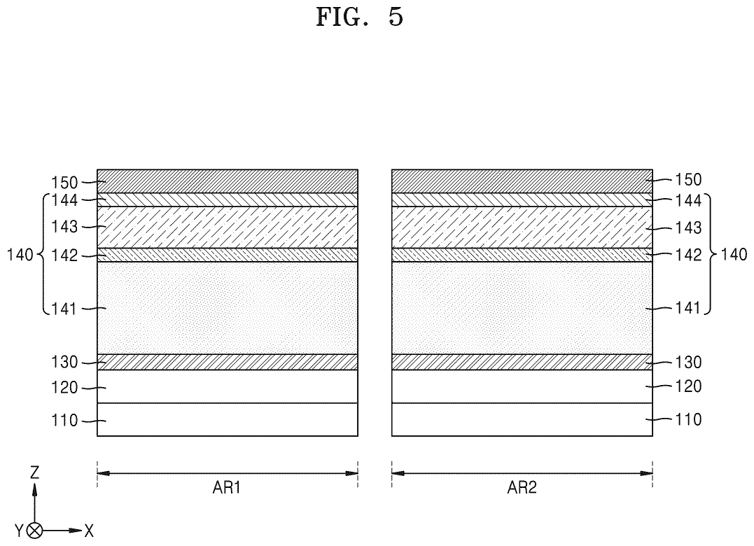

Referring to FIG. 5, a hardmask structure 140 including a plurality of hardmask layers may be formed on the etch target film 130. A first photoresist film 150 may be formed on the hardmask structure 140 in the first and second regions AR1 and AR2. In the first and second regions AR1 and AR2, the first photoresist film 150 may cover the top surface of the hardmask structure 140.

The hardmask structure 140 may include a lower hardmask layer 141, a main hardmask layer 142, an upper hardmask layer 143, and an anti-reflective layer 144, which are sequentially stacked on the etch target film 130. Each of the lower hardmask layer 141, the main hardmask layer 142, the upper hardmask layer 143, and the anti-reflective layer 144 may include a material that has a different etch selectivity than other adjacent layers therebelow and thereabove.

In some example embodiments, the lower hardmask layer 141 may include an amorphous carbon layer (ACL), a silicon oxide film, or a silicon nitride film. The lower hardmask layer 141 may have a thickness of about 1000 Å to about 2000 Å. In some example embodiments, the main hardmask layer 142 may include polysilicon. The main hardmask layer 142 may have a thickness of about 100 Å to about 400 Å. For example, the upper hardmask layer 143 may include a hydrocarbon compound, which has a relatively high carbon content of about 85 wt % to about 99 wt % based on the total weight thereof, or a spin-on hardmask (SOH) including a derivative thereof. The upper hardmask layer 143 may have a thickness of about 300 Å to about 1000 Å. The anti-reflective layer 144 may include silicon nitride, silicon oxynitride, amorphous silicon, titanium, titanium dioxide, titanium nitride, chromium oxide, carbon, an organic anti-reflective coating (ARC) material, or a combination thereof. The anti-reflective layer 144 may have a thickness of about 200 Å to about 400 Å.

The first photoresist film 150 may include a resist for extreme ultraviolet (EUV) light (13.5 nm), a resist for KrF excimer laser light (248 nm), a resist for ArF excimer laser light (193 nm), and/or a resist for F₂ excimer laser light (157 nm). The first photoresist film 150 may include metal and an inorganic material. For example, the first photoresist film 150 may include a metal oxide resist (MOR). The first photoresist film 150 may be formed by a vapor deposition process and/or a spin coating process.

For example, the description below is made assuming that the first photoresist film 150 includes a negative tone photoresist material.

The first photoresist film 150 may be arranged in the first region AR1 and the second region AR2. Accordingly, the top surface of the hardmask structure 140 in each of the first region AR1 and the second region AR2 may not be exposed to the outside.

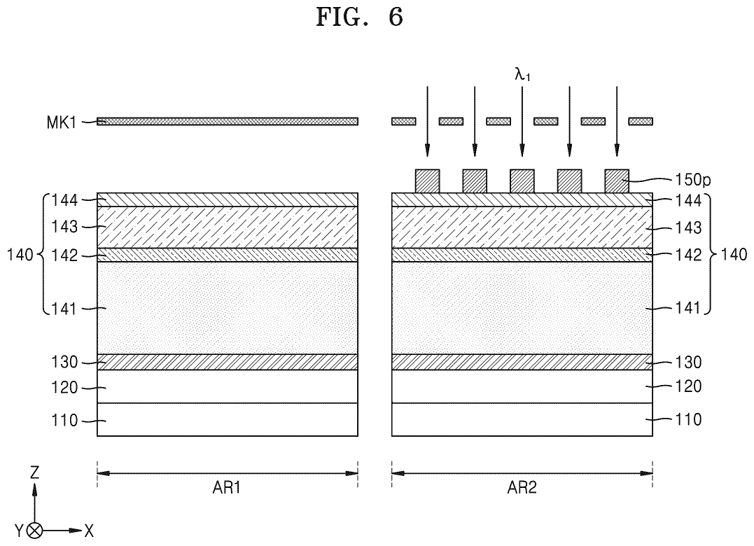

Referring to FIG. 6, a first photoresist pattern 150p may be formed from the first photoresist film 150 by performing exposure and development on the first photoresist film 150 in FIG. 5. The first photoresist film 150 (in FIG. 5) may be exposed to light, which has a first wavelength λ₁ and has penetrated through a first mask MK1. For example, the first wavelength λ₁ may be about 13.5 nm. In other words, light having the first wavelength λ₁ may be EUV light. Accordingly, the first photoresist pattern 150p may be formed by EUV lithography.

Because the first photoresist film 150 (in FIG. 5) includes a negative tone photoresist material, a portion of the first photoresist film 150 that is not exposed to the light may be removed by development. Accordingly, the first mask MK1 may be closed in the first region AR1 and open in at least a portion of the second region AR2. When a mask is closed, it means that light incident to the mask does not penetrate through the mask. When a mask is open, it means that light incident to the mask penetrates through the mask.

Accordingly, the first photoresist pattern 150p may be formed in a portion corresponding to an open region of the first mask MK1. Accordingly, the top surface of the hardmask structure 140 in the first region AR1 may be entirely exposed to the outside, and at least a portion of the top surface of the hardmask structure 140 in the second region AR2 may not exposed to the outside. The exposure ratio of the top surface of the hardmask structure 140 in the first region AR1 may be greater than the exposure ratio of the top surface of the hardmask structure 140 in the second region AR2.

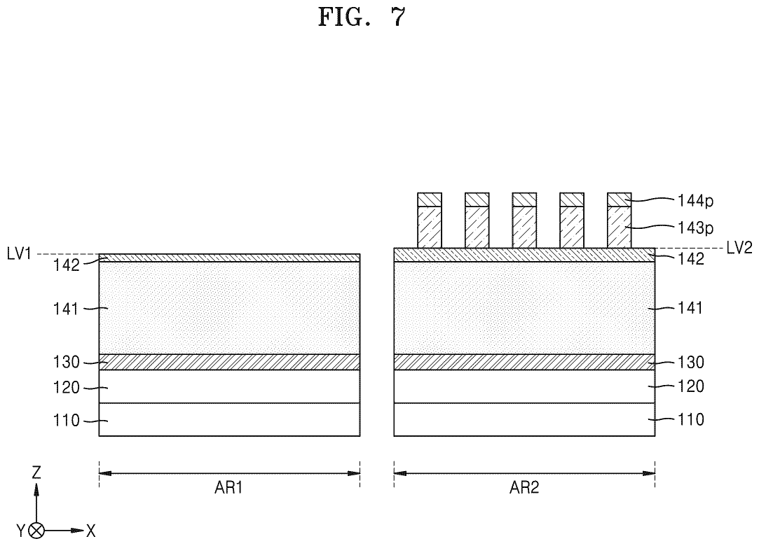

Referring to FIG. 7, the anti-reflective layer 144 (in FIG. 6) and the upper hardmask layer 143 (in FIG. 6) may be sequentially etched. Because the first photoresist pattern 150p (in FIG. 6) is not formed in the first region AR1, each of the anti-reflective layer 144 (in FIG. 6) and the upper hardmask layer 143 (in FIG. 6) may be entirely removed in the first region AR1. Accordingly, the top surface of the main hardmask layer 142 may be entirely exposed to the outside in the first region AR1.

Contrarily, because the first photoresist pattern 150p (in FIG. 6) is formed in the second region AR2, the first photoresist pattern 150p (in FIG. 6) may function as an etch mask such that an upper hardmask pattern 143p and an anti-reflective pattern 144p, to which the shape of the first photoresist pattern 150p (in FIG. 6) is transferred, are formed.

In the second region AR2, each of the first photoresist pattern 150p, the upper hardmask layer 143 (in FIG. 6), and the anti-reflective layer 144 (in FIG. 6) may be at least partially consumed while the etching process is being performed until the upper hardmask pattern 143p and the anti-reflective pattern 144p are obtained. The top surface of the anti-reflective pattern 144p may be exposed by removing unnecessary materials remaining on the anti-reflective pattern 144p.

A portion of the top surface of the main hardmask layer 142 in the second region AR2 may be exposed to the outside. For example, the top surface of the main hardmask layer 142 may be exposed at a location where there is neither the upper hardmask pattern 143p nor the anti-reflective pattern 144p.

Before the upper hardmask layer 143 (in FIG. 6) and the anti-reflective layer 144 (in FIG. 6) are etched, the top surface of the anti-reflective layer 144 in the first region AR1 may have been entirely exposed to the outside and the top surface of the anti-reflective layer 144 in the second region AR2 may have been at least partially covered with the first photoresist pattern 150p (in FIG. 6). Accordingly, the etching amount of the upper hardmask layer 143 (in FIG. 6) and the anti-reflective layer 144 (in FIG. 6) in the first region AR1 may be different from the etching amount of the upper hardmask layer 143 (in FIG. 6) and the anti-reflective layer 144 (in FIG. 6) in the second region AR2. In other words, the top surface of the main hardmask layer 142 in the first region AR1 may be at a first level LV1 and the top surface of the main hardmask layer 142 in the second region AR2 may be at a second level LV2. The first level LV1 may be at a different vertical level than the second level LV2.

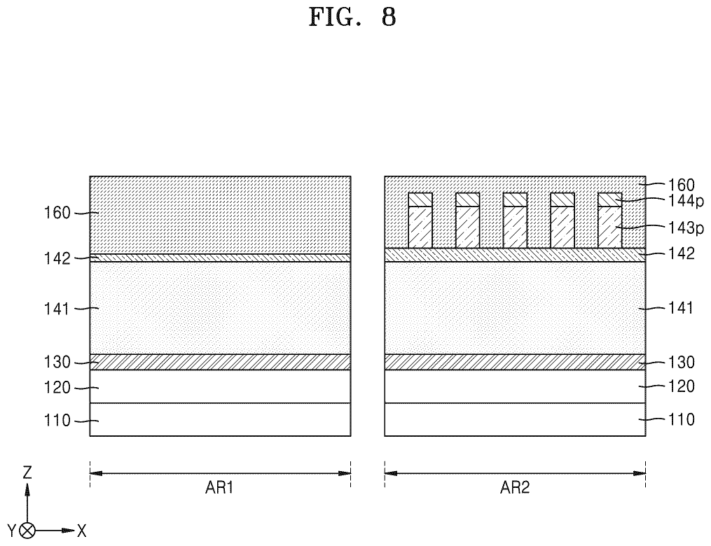

Referring to FIG. 8, a second photoresist film 160 may be formed in the first region AR1 and the second region AR2. The second photoresist film 160 may include a resist for EUV light (13.5 nm), a resist for KrF excimer laser light (248 nm), a resist for ArF excimer laser light (193 nm), and/or a resist for F₂ excimer laser light (157 nm). The second photoresist film 160 may include metal and an inorganic material. For example, the second photoresist film 160 may include an MOR. The second photoresist film 160 may be formed by a vapor deposition process and/or a spin coating process.

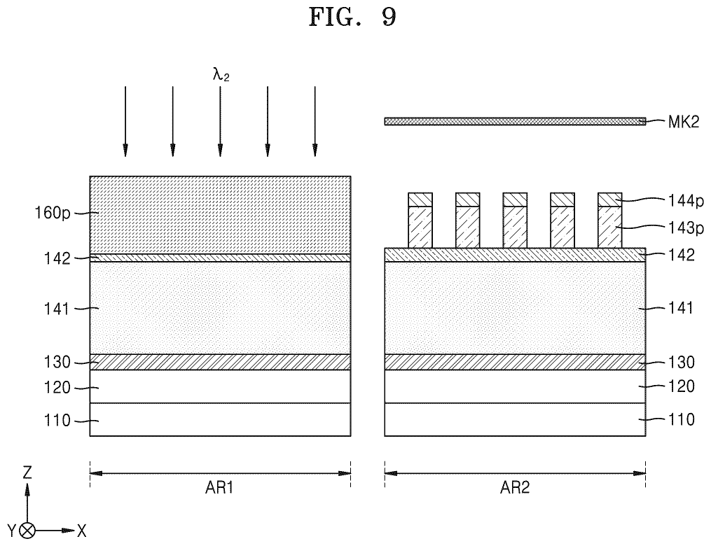

Referring to FIG. 9, a second photoresist pattern 160p may be formed by performing exposure and development on the second photoresist film 160 in FIG. 8. The second photoresist film 160 (in FIG. 8) may be exposed to light, which has a second wavelength λ₂ and has penetrated through a second mask MK2. For example, the second wavelength λ₂ may be about 157 nm, about 193 nm, or about 248 nm. The second wavelength λ₂ may be longer than the first wavelength λ₁. The second photoresist film 160 (in FIG. 8) may be exposed to KrF excimer laser light (248 nm), ArF excimer laser light (193 nm), or F₂ excimer laser light (157 nm).

In a method of forming a pattern, according to the inventive concepts, patterns may be formed only in a single region (the first region AR1 or the second region AR2). FIGS. 4 to 13 illustrate a method of forming patterns only in the second region AR2, and therefore, a pattern may not be formed in the first region AR1. Accordingly, the second photoresist pattern 160p may cover the entire top surface of the main hardmask layer 142.

Different wavelengths give rise to distinct optical proximity effects. Accordingly, the process of forming the first photoresist pattern 150p (in FIG. 6) may be different from the process of forming the second photoresist pattern 160p. In detail, a process of exposing the first photoresist pattern 150p (in FIG. 6) may be different from a process of exposing the second photoresist pattern 160p (in FIG. 8). Accordingly, the curvature of the edge of the first photoresist pattern 150p (in FIG. 6) may be different from the curvature of the edge of the second photoresist pattern 160p (in FIG. 8).

The second photoresist pattern 160p may be arranged only in the first region AR1 and may entirely cover the top surface of the main hardmask layer 142 in the first region AR1. The top surface of the main hardmask layer 142 in the second region AR2 may be exposed to the outside. The exposure ratio of the top surface of the main hardmask layer 142 in the first region AR1 may be less than the exposure ratio of the top surface of the main hardmask layer 142 in the second region AR2.

The second mask MK2 may be open in the first region AR1 and closed in the second region AR2. Accordingly, the second photoresist pattern 160p may be formed in a region that overlaps the open region of the second mask MK2.

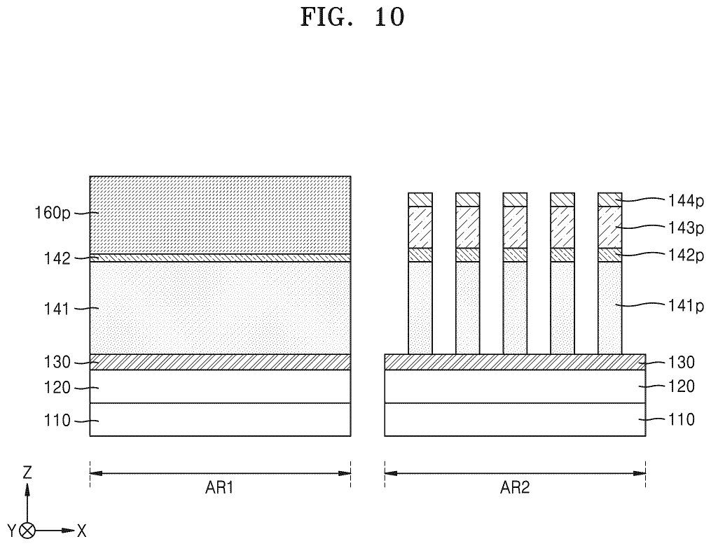

Referring to FIG. 10, in the second region AR2, a lower hardmask pattern 141p and a main mask pattern 142p, to which the shape of each of the upper hardmask pattern 143p and the anti-reflective pattern 144p is transferred, may be formed by using the upper hardmask pattern 143p and the anti-reflective pattern 144p as an etch mask.

Because the second photoresist pattern 160p is formed in the first region AR1, the lower hardmask layer 141 and the main hardmask layer 142 in the first region AR1 may not be removed and each of the lower hardmask layer 141 and the main hardmask layer 142 in the second region AR2 may be at least partially removed. Accordingly, at least a portion of the top surface of the etch target film 130 in the second region AR2 may be exposed to the outside.

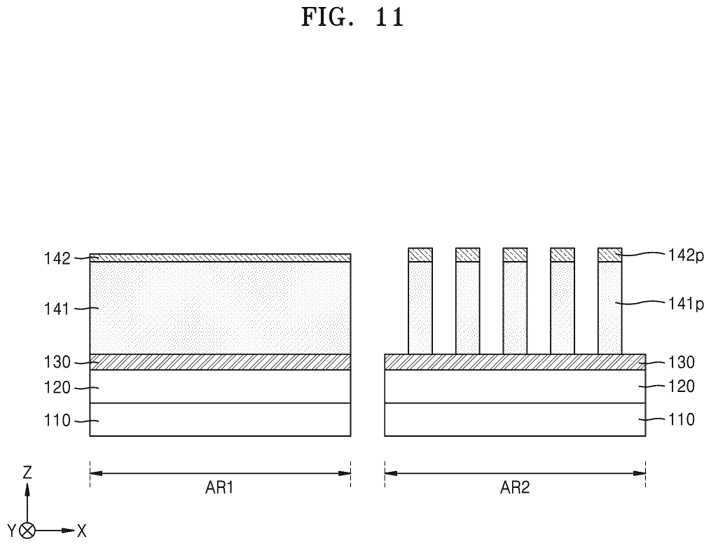

Referring to FIG. 11, the second photoresist pattern 160p (in FIG. 10) in the first region AR1 may be removed. Accordingly, the top surface of the main hardmask layer 142 in the first region AR1 may be exposed to the outside. The upper hardmask pattern 143p (in FIG. 10) and the anti-reflective pattern 144p (in FIG. 10) in the second region AR2 may be removed.

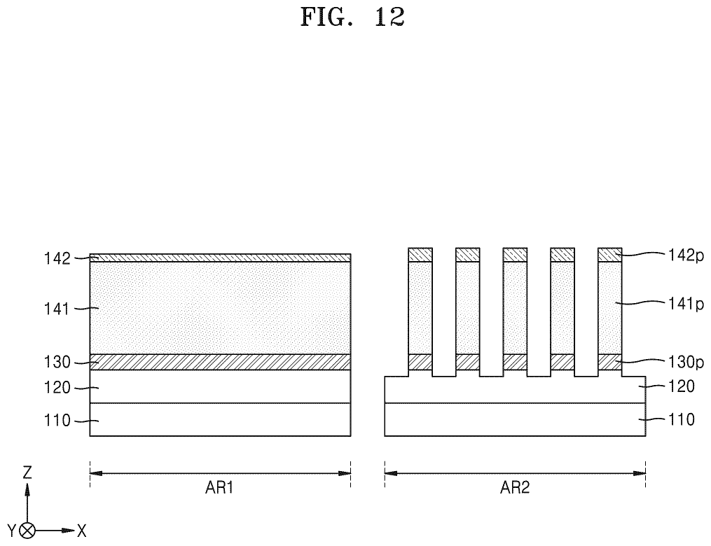

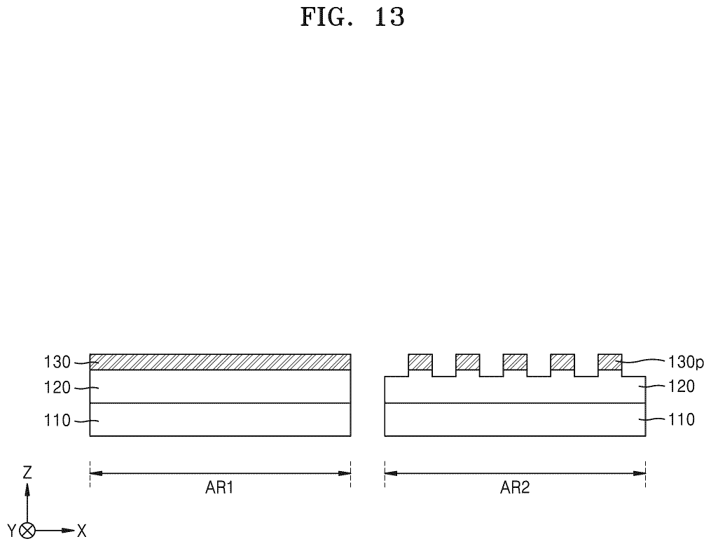

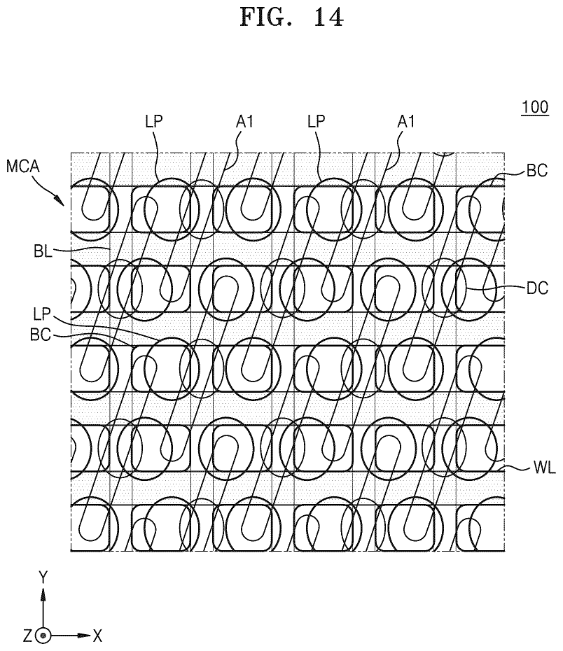

Referring to FIG. 12, an etch pattern 130p may be formed by at least partially removing the etch target film 130 (in FIG. 11) by using the lower hardmask pattern 141p and the main mask pattern 142p in FIG. 11 as an etch mask. Because the lower hardmask layer 141 and the main hardmask layer 142 cover the entire top surface of the etch target film 130 in the first region AR1, the etch target film 130 in the first region AR1 may not be etched.

Contrarily, because the top surface of the etch target film 130 in the second region AR2 is at least partially exposed by the lower hardmask pattern 141p and the main mask pattern 142p, the etch target film 130 may be at least partially removed.

Referring to FIG. 13, the lower hardmask layer 141 (in FIG. 12) and the main hardmask layer 142 (in FIG. 12) in the first region AR1 may be etched and the lower hardmask pattern 141p (in FIG. 12) and the main mask pattern 142p (in FIG. 12) in the second region AR2 may be etched. Accordingly, the top surface of the etch target film 130 in the first region AR1 may be flat and the top surface of the etch pattern 130p in the second region AR2 may have a concave-convex shape.

In the method of forming patterns, according to the inventive concepts, a pattern in the first region AR1 and a pattern in the second region AR2 may be formed at different times. Because a photomask in a region, in which a pattern is not formed, is exposed by using a relatively long wavelength, the dose of a relatively short wavelength (e.g., an EUV wavelength) may be reduced. Accordingly, the overall cost of the process may be reduced.

In the method of forming patterns, according to the inventive concepts, patterns may be formed only in a single region (the first region AR1 or the second region AR2) by a single process (the process described with reference to FIGS. 4 to 13). Because patterns are formed only in a single region, a variation in the critical dimensions (CD) of the patterns may be small. Accordingly, the pattern forming method of the inventive concepts may increase the reliability of patterns by easily controlling the degree of exposure of the first photoresist film 150.

The method of forming patterns only in the second region AR2 but not in the first region AR1 has been described above. A method of forming patterns only in the first region AR1 but not in the second region AR2 may be easily derived by one of skill in the art. Accordingly, a method of forming patterns in the first region AR1 and/or the second region AR2 is provided.

FIG. 14 is a schematic plane layout illustrating main elements in a cell array region MCA in FIG. 2. FIG. 14 is described with reference to FIGS. 1 to 3.

Referring to FIG. 14, the cell array region MCA may include a plurality of cell active regions A1. Each of the cell active regions A1 may be arranged to have a long axis in a diagonal direction to a first horizontal direction (the X direction) and a second horizontal direction (the Y direction). A plurality of word lines WL may extend across the cell active regions A1 in the first horizontal direction (the X direction) and may be parallel with each other. A plurality of bit lines BL may be above the word lines WL to be parallel with each other and may extend in the second horizontal direction (the Y direction). Each of the bit lines BL may be connected to one of the cell active regions A1 through a direct contact DC. A plurality of buried contacts BC may be formed between two adjacent bit lines BL. The buried contacts BC may be arranged in lines in the first horizontal direction (the X direction) and the second horizontal direction (the Y direction). A plurality of conductive landing pads LP may be respectively on the buried contacts BC. Each of the buried contacts BC and each of the conductive landing pads LP may connect a lower electrode (not shown) of a capacitor on one of the bit lines BL to one of the cell active regions A1. Each of the conductive landing pads LP may at least partially overlap with one of the buried contacts BC in a vertical direction.

FIG. 15 is a plan view illustrating an example arrangement of conductive patterns in a peripheral circuit region of the semiconductor memory device 100, according to example embodiments. FIG. 15 is described with reference to FIGS. 1 to 3.

Referring to FIG. 15, a plurality of conductive patterns CNP may be arranged in the second region 24 of the semiconductor memory device 100 of FIGS. 1 and 2. Some of the conductive patterns CNP may extend to be parallel with each other. Some of the conductive patterns CNP may function as conductive pads that connect a lower conductive region to an upper conductive region. The conductive patterns CNP may be apart from one another with spaces of various sizes thereamong in the horizontal direction, e.g., the first horizontal direction (the X direction) and the second horizontal direction (the Y direction). In some parts of the second region 24, the minimum distance between two adjacent conductive patterns CNP may be the minimum feature size of the semiconductor memory device 100. In other parts of the second region 24, the minimum distance between two adjacent conductive patterns CNP may be several to tens of times the minimum feature size of the semiconductor memory device 100.

The horizontal widths, e.g., the width in the first horizontal direction (the X direction) and the width in the second horizontal direction (the Y direction), of each of the conductive patterns CNP and the horizontal distances, e.g., the distance in the first horizontal direction (the X direction) and the distance in the second horizontal direction (the Y direction), between the conductive patterns CNP may vary.

The conductive landing pads LP in FIG. 14 and the conductive patterns CNP in FIG. 15 may be formed by a series of processes including a plurality of exposure processes. In some example embodiments, the series of processes of forming each of the conductive landing pads LP in FIG. 14 and the conductive patterns CNP in FIG. 15 may include an exposure process using an EUV light source and an exposure process using a KrF excimer laser light source (248 nm), an ArF excimer laser light source (193 nm), and/or an F₂ excimer laser light source (157 nm).

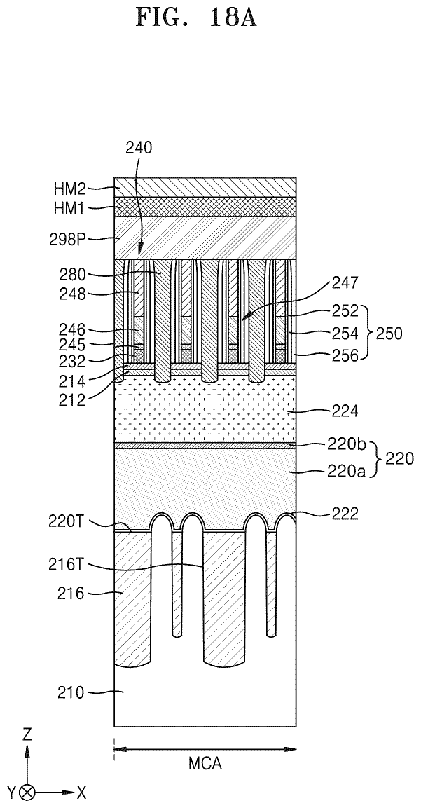

FIGS. 16A to 20B are cross-sectional views illustrating a method of manufacturing a semiconductor memory device 1, according to example embodiments. FIGS. 16A to 20B are described with reference to FIGS. 1 to 15. In detail, FIGS. 16A, 17A, 18A, 19A, and 20A are cross-sectional views of a cell array region MCA in FIG. 14 and FIGS. 16B, 17B, 18B, 19B, and 20B are cross-sectional views of a peripheral circuit region CORE/PERI in FIG. 15. FIGS. 16A to 20B illustrate a method of forming pattern only in the peripheral circuit region CORE/PERI. FIGS. 16A to 20B illustrate a wiring method of the semiconductor memory device 1.

Referring to FIGS. 16A and 16B, a substrate 210, a first insulating film pattern 212, a second insulating film pattern 214, a peripheral device isolation film 215, a device isolation film 216, a word line 220, a buried insulating film 224, a bit line structure 240, an insulating spacer 250, and an insulating fence 280 may be formed in the cell array region MCA and the peripheral circuit region CORE/PERI.

In the cell array region MCA, a device isolation trench 216T may be formed to penetrate through the substrate 210 and the device isolation film 216 may be formed in the device isolation trench 216T. A plurality of word line trenches 220T may be formed in the substrate 210. The word line trenches 220T may extend in the first horizontal direction (the X direction) to be parallel with each other, cross the active regions 218, and may be arranged at regular intervals in the second horizontal direction (the Y direction). Each of the word line trenches 220T may have a line shape. In some example embodiments, a step may be formed in the bottom surface of each of the word line trenches 220T. A plurality of word lines 220 may respectively form the word lines WL in FIG. 14. Thereafter, a gate dielectric film 222, a lower word line 220a, and an upper word line 220b may be sequentially formed on the substrate 210. The buried insulating film 224, the first insulating film pattern 212, and the second insulating film pattern 214 may be sequentially stacked on the word line 220.

Thereafter, a conductive semiconductor pattern 232, a first metal conductive pattern 245, a second metal conductive pattern 246, and/or an insulating capping line 248 may be sequentially stacked on the second insulating film pattern 214. First to third insulating spacers 252, 254, and 256 may be formed to surround the sidewall of each of the conductive semiconductor pattern 232, the first metal conductive pattern 245, the second metal conductive pattern 246, and the insulating capping line 248.

Thereafter, the insulating fence 280 may be formed adjacent to the insulating spacer 250 to penetrate through at least a portion of each of the first insulating film pattern 212, the second insulating film pattern 214, and the buried insulating film 224. A preliminary insulating material layer 298P may be formed on the insulating fence 280. The preliminary insulating material layer 298P may correspond to the etch target film 130 in FIG. 4.

In the peripheral circuit region CORE/PERI, a peripheral device isolation trench 215T may be formed to penetrate through at least a portion of the substrate 210 and the peripheral device isolation film 215 may be formed in the peripheral device isolation trench 215T. Thereafter, the first insulating film pattern 212 and the second insulating film pattern 214 may be sequentially stacked on the substrate 210.

Thereafter, a gate line structure 240P may be formed on a peripheral active region 217. The gate line structure 240P may include a gate line 247P, an insulating capping line 248 covering the gate line 247P, and a gate insulating spacer 250P covering the sidewall of each of the gate line 247P and the insulating capping line 248. The gate line 247P may have a stack structure of the first metal conductive pattern 245 and the second metal conductive pattern 246. A gate insulating film pattern 242 may be arranged between the gate line 247P and the peripheral active region 217. In some example embodiments, the gate line structure 240P may further include a conductive semiconductor pattern 232 between the gate insulating film pattern 242 and the first metal conductive pattern 245. A plurality of gate lines 247P may form the conductive patterns CNP in FIG. 15.

Thereafter, a first filling insulating layer 272 may be formed on the sidewall of the gate line structure 240P and a second filling insulating layer 274 may be formed on the first filling insulating layer 272 and the gate line structure 240P. Thereafter, a contact plug CP may be formed to penetrate through at least a portion of each of the substrate 210, the first insulating film pattern 212, the second insulating film pattern 214, the first filling insulating layer 272, and the second filling insulating layer 274. A plurality of contact holes CPH may be formed to pass through the second filling insulation layer 174, the first filling insulation layer 172, and the insulating film pattern (including the first and second insulating film patterns 112 and 114). The contact plug CP may fill the plurality of contact holes CPH. The preliminary insulating material layer 298P may be formed on the second filling insulating layer 274. The preliminary insulating material layer 298P may correspond to the etch target film 130.

In the cell array region MCA, a hardmask structure HM may be formed to cover the entire top surface of the preliminary insulating material layer 298P. The hardmask structure HM may include first to fourth hardmask layers HM1, HM2, HM3, and HM4. In the peripheral circuit region CORE/PERI, the hardmask structure HM and a first photoresist pattern PR1 may be formed on the preliminary insulating material layer 298P. In the cell array region MCA, the entire top surface of the hardmask structure HM may be exposed to the outside. In the peripheral circuit region CORE/PERI, at least a portion of the top surface of the hardmask structure HM may be covered with the first photoresist pattern PR1.

Referring to FIGS. 17A and 17B, in the cell array region MCA, the third and fourth hardmask layers HM3 and HM4 (in FIG. 16A) may be removed and a second photoresist pattern PR2 may be formed. The second photoresist pattern PR2 may cover the entire top surface of the second hardmask layer HM2.

In the peripheral circuit region CORE/PERI, a third hardmask pattern HM3P and a fourth hardmask pattern HM4P may be formed by removing at least a portion of each of the third and fourth hardmask layers HM3 and HM4 (in FIG. 16B) by using the first photoresist pattern PR1 (in FIG. 16B) as an etch mask. The third hardmask pattern HM3P and the fourth hardmask pattern HM4P may expose at least a portion of the top surface of the second hardmask layer HM2.

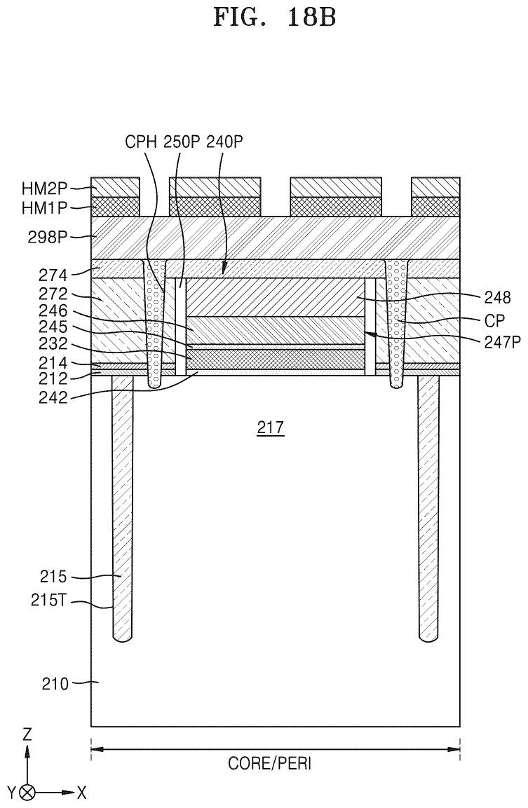

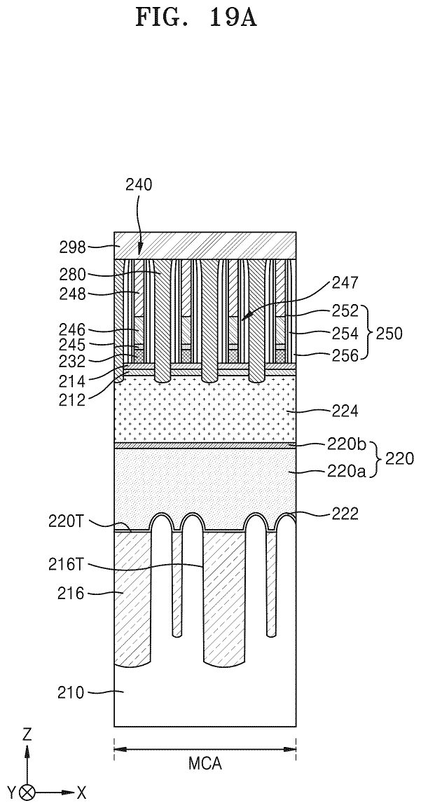

Referring to FIGS. 18A and 18B, in the cell array region MCA, the second photoresist pattern PR2 (in FIG. 17A) may be removed such that the top surface of the second hardmask layer HM2 is exposed. Each of the first and second hardmask layers HM1 and HM2 may cover the entire top surface of the preliminary insulating material layer 298P.

In the peripheral circuit region CORE/PERI, a first hardmask pattern HM1P and a second hardmask pattern HM2P may be formed by removing at least a portion of each of the first and second hardmask layers HM1 and HM2 (in FIG. 17B) by using the third hardmask pattern HM3P (in FIG. 17B) and the fourth hardmask pattern HM4P (in FIG. 17B) as an etch mask. Thereafter, the third hardmask pattern HM3P (in FIG. 17B) and the fourth hardmask pattern HM4P (in FIG. 17B) may be removed. The first hardmask pattern HM1P and the second hardmask pattern HM2P may expose at least a portion of the top surface of the preliminary insulating material layer 298P.

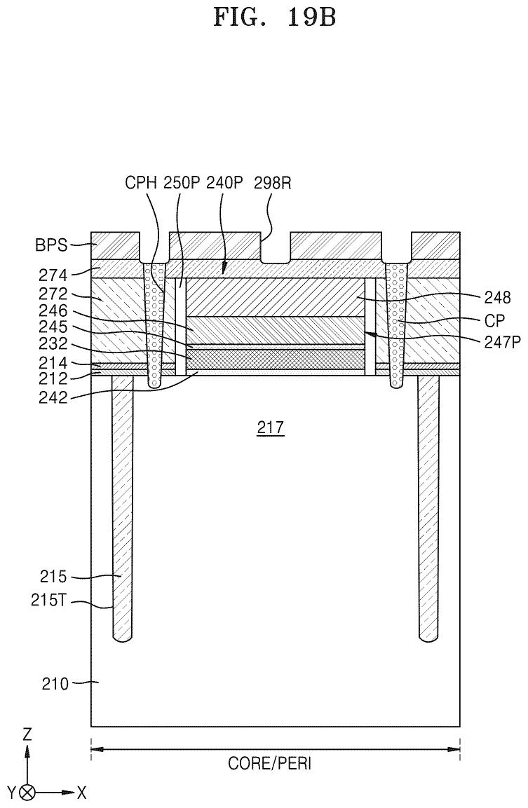

Referring to FIGS. 19A and 19B, in the cell array region MCA, the first and second hardmask layers HM1 and HM2 (in FIG. 18A) may be removed. At least a portion of the preliminary insulating material layer 298P (in FIG. 18A) may also be removed so that an insulating material layer 298 may be formed. In some example embodiments, the insulating material layer 298 may be formed without removing the preliminary insulating material layer 298P (in FIG. 18A).

In the peripheral circuit region CORE/PERI, a plurality of peripheral bit line recesses 298R may be formed by at least partially removing the preliminary insulating material layer 298P (in FIG. 18B) by using the first hardmask pattern HM1P (in FIG. 18B) and the second hardmask pattern HM2P (in FIG. 18B) as an etch mask. Thereafter, the first hardmask pattern HM1P (in FIG. 18B) and the second hardmask pattern HM2P (in FIG. 18B) may be removed. A peripheral bit line insulating structure BPS may be formed by forming the peripheral bit line recesses 298R in the preliminary insulating material layer 298P (in FIG. 18B).

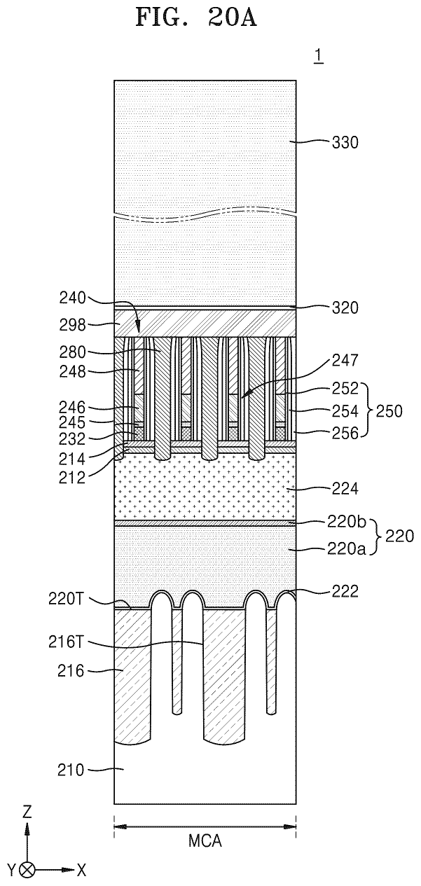

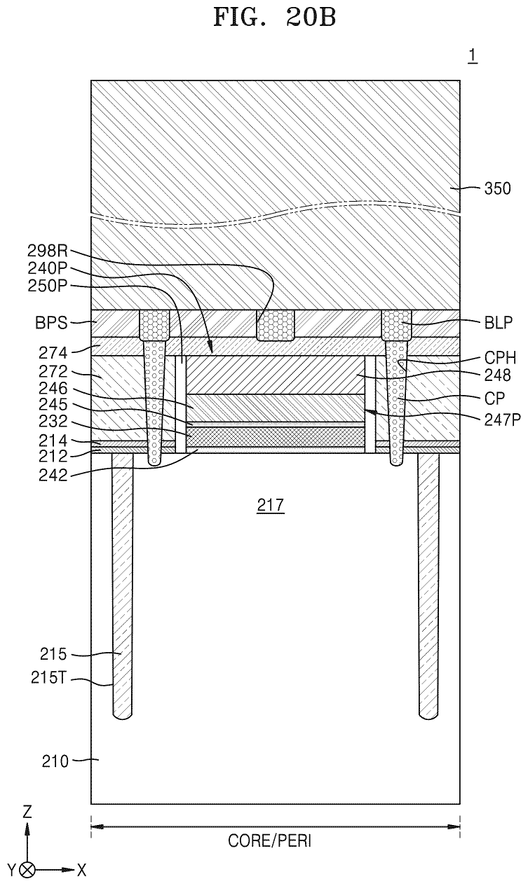

Referring to FIGS. 20A and 20B, a plurality of peripheral bit lines BLP may be formed in the peripheral bit line recesses 298R. Thereafter, in the cell array region MCA, a capacitor dielectric layer 320 and an upper electrode 330 may be sequentially formed on the resultant structure of FIG. 19A so that the semiconductor memory device 1 may be formed.

In the peripheral circuit region CORE/PERI, a burying insulation layer 350 may be formed to cover the peripheral bit lines BLP and the peripheral bit line insulating structure BPS so that the semiconductor memory device 1 may be formed.

Example embodiments where a pattern is not formed in the cell array region MCA but is formed only in the peripheral circuit region CORE/PERI has been described as an example, but the inventive concepts are not limited thereto. For example, after the processes described with reference to FIGS. 16A to 20B are performed, a process of forming a pattern only in the cell array region MCA may be additionally performed.

While the inventive concepts have been particularly shown and described with reference to example embodiments thereof, it will be understood that various changes in form and details may be made therein without departing from the spirit and scope of the following claims.

What is claimed is:

1. A method of forming patterns, the method comprising:
forming an etch target film on a substrate having a first region and a second region;
forming a hardmask structure on the etch target film in the first region and the second region, the hardmask structure including a plurality of hardmask layers;
forming a first photoresist film on the hardmask structure in at least one of the first region and the second region;
forming a first photoresist pattern in the second region by exposing and developing the first photoresist film; and
forming a pattern from the etch target film by etching the hardmask structure and the etch target film by using the first photoresist pattern,
wherein a top surface of the hardmask structure in the first region is exposed to the outside after the first photoresist film is developed.

2. The method of claim 1, further comprising:
forming a second photoresist film on the hardmask structure in at least one of the first region and the second region; and
forming a second photoresist pattern covering the first region by exposing and developing the second photoresist film,
wherein the second photoresist pattern is formed after at least one of the plurality of hardmask layers is removed.

3. The method of claim 2, wherein the second photoresist pattern entirely covers the top surface of the hardmask structure.

4. The method of claim 1, wherein the first photoresist pattern exposes at least a portion of the hardmask structure.

5. The method of claim 2, wherein a first wavelength of light exposing the first photoresist film is different from a second wavelength of light exposing the second photoresist film.

6. The method of claim 2, wherein, in a plan view, a curvature of an edge of the first photoresist pattern is different from a curvature of an edge of the second photoresist pattern.

7. The method of claim 2, wherein the first photoresist film and the second photoresist film include metal.

8. The method of claim 1, wherein, in a plan view, the second region surrounds the first region.

9. A method of forming patterns, the method comprising:
forming an etch target film on a substrate having a first region and a second region;
forming a hardmask structure including a lower hardmask layer, a main hardmask layer, and an upper hardmask layer sequentially stacked on the etch target film;
forming a first photoresist pattern on the hardmask structure by exposing the second region to light having a first wavelength;
forming a hardmask pattern by removing the upper hardmask layer in the first region and removing at least a portion of the upper hardmask layer in the second region by using the first photoresist pattern as an etch mask;
forming a second photoresist pattern on the main hardmask layer by exposing the first region to light having a second wavelength; and
forming a pattern from the etch target film by using the hardmask pattern,
wherein the first photoresist pattern is arranged only in the second region and the second photoresist pattern is arranged only in the first region.

10. The method of claim 9, wherein the second photoresist pattern entirely covers a top surface of the main hardmask layer.

11. The method of claim 9, wherein,
in the forming of the second photoresist pattern,
a vertical level of a top surface of the main hardmask layer in the first region is different from a vertical level of the top surface of the main hardmask layer in the second region.

12. The method of claim 9, wherein the first wavelength is shorter than the second wavelength.

13. The method of claim 9, wherein a density of the pattern in the first region is different from a density of the pattern in the second region.

14. The method of claim 10, wherein
each of the first photoresist pattern and the second photoresist pattern is formed by forming a photoresist film and exposing and developing the photoresist film, and
the photoresist film is formed by at least one of a vapor deposition process and a spin coating process.

15. The method of claim 9, wherein the first photoresist pattern and the second photoresist pattern include metal oxide photoresist (MOR).

16. A method of manufacturing a semiconductor memory device, the method comprising:
forming an etch target film on a substrate having a cell array region and a peripheral circuit region;
forming a hardmask structure on the etch target film in the cell array region and the peripheral circuit region, the hardmask structure including a plurality of hardmask layers;
forming a first photoresist film on the hardmask structure in the cell array region and the peripheral circuit region;
forming a first photoresist pattern in the peripheral circuit region by exposing and developing the first photoresist film;
forming a second photoresist film on the hardmask structure in at least one of the cell array region and the peripheral circuit region;
forming a second photoresist pattern covering the cell array region by exposing and developing the second photoresist film; and
forming a pattern from the etch target film by etching the hardmask structure and the etch target film by using the first and second photoresist patterns,
wherein a top surface of the hardmask structure in the cell array region is exposed to the outside after the first photoresist film is developed, and
the second photoresist film is formed after at least one of the plurality of hardmask layers is removed.

17. The method of claim 16, wherein
the first photoresist pattern exposes at least a portion of the top surface of the hardmask structure, and
the second photoresist pattern entirely covers the top surface of the hardmask structure.

18. The method of claim 16, wherein the first photoresist film is exposed to light through a mask having an open region in correspondence to the cell array region.

19. The method of claim 16, wherein the second photoresist film is exposed to light through a mask having a closed region in correspondence to the cell array region.

20. The method of claim 16, wherein
the first photoresist pattern is formed by an exposure process using an extreme ultraviolet (EUV) light source, and
the second photoresist pattern is formed by an exposure process using at least one selected from the group consisting of an ArF light source, a KrF light source, and an F₂ light source.
